(19) United States
(12) Patent Application Publication
(10) Pub. No.: US 2017/0040488 A1
(43) Pub. Date: Feb. 9, 2017

(54) SPATIALLY-ANNEALED NANOPARTICLE FILMS AND METHODS OF MAKING AND USING SAME

(71) Applicant: Cornell University, Ithaca, NY (US)

(72) Inventors: Tobias Hanrath, Ithaca, NY (US); Ben E. Treml, Ithaca, NY (US)

(21) Appl. No.: 15/227,306

(22) Filed: Aug. 3, 2016

Related U.S. Application Data
(60) Provisional application No. 62/200,457, filed on Aug. 3, 2015.

(51) Int. Cl. H01L 33/00; H01L 33/50; C09K 11/88; H01L 33/06

(52) U.S. Cl. CPC H01L 33/0095; H01L 33/06; H01L 33/505; C09K 11/883; H01L 2933/0041; B82Y 40/00

(57) ABSTRACT

Provided are spatially-annealed nanoparticle films. The films have one or more discrete regions that exhibit size-dependent properties. Also provided are methods of making the spatially-annealed nanoparticle films. The films can be used in, for example, light emitting applications (e.g., in light emitting diodes).

### CROSS REFERENCE TO RELATED APPLICATIONS

This application claims priority to U.S. Provisional Application No. 62/200,457, filed on Aug. 3, 2015, the disclosure of which is hereby incorporated by reference.

### STATEMENT REGARDING FEDERALLY SPONSORED RESEARCH

This invention was made with government support under grant numbers DMR-1120296, ECCS-1542081, and DMR-1056943 awarded by the National Science Foundation. The government has certain rights in the invention.

### FIELD OF THE DISCLOSURE

The disclosure generally relates to annealed nanoparticle films and methods of making and using same. More particularly the disclosure generally relates to spatially-annealed nanoparticle films and methods of making and using same.

### BACKGROUND OF THE DISCLOSURE

Colloidal semiconductor nanoparticles, also commonly referred to as nanocrystals (NCs) or quantum dots (QD), provide versatile building blocks for emerging optoelectronic applications. By virtue of fundamental quantum confinement effects, their absorption and emission characteristics can be rigorously controlled by adjusting the size of the NC, or also commonly referred to as quantum dot. Recent advances in NC synthesis and improved understanding of the basic photophysical properties have led to remarkable advances yielding NC emitters with stable and narrow emission. Among the various proposed nanocrystal technologies, their application as emitters in displays and diodes have advanced most rapidly; to the point where commercial LED displays that utilize QD emitters are now available.

In parallel to the advances in the synthesis of precisely tailored building blocks, significant progress has also been made in assembling NCs into ordered superstructures. However, critical challenges persist in the formation of creating superstructures in which constituent NCs can purposefully interact due to the presence of insulating NC ligands. Several chemical and physical approaches have been developed to address this challenge, including ligand exchange, thermal annealing, and high pressure treatments. An exciting, yet unexplored, opportunity of physical processing methods is the ability to apply the processing with precise spatial resolution. Successful development of this approach would provide new avenues to create programmable properties in thin films by exploiting patterning and size-dependent properties

### SUMMARY OF THE DISCLOSURE

The present disclosure describes how laser spike annealing (LSA) on nanoparticle films, e.g., CdSe nanocrystal (NC) thin films, yields thin films with in which size dependent PL emission can be tuned, e.g., throughout the visible range and in spatially defined profiles, in a single annealing step. Through control over the annealing temperature and time it was established that NC fusion is a kinetically limited process with a constant activation energy over two orders of magnitude of NC growth rate. Lastly, the scalability of LSA to process large area NC films with periodically modulated PL emission, resulting in tunable emission properties of a large area film, was demonstrated. New insights into the processing-structure-property relationships described herein offer significant advances in our fundamental understanding of kinetic of nanomaterial fusion as well as technological implications for the production of nanomaterial films with periodically modulated optical properties.

In an aspect, the present disclosure provides methods of spatially annealing nanoparticle films. The methods are based on exposing/contacting specific regions of the film with focused light such that two or more of the nanoparticles in the specific region of the film are fused, which results in changes in the optical, electronic, and/or magnetic properties of the specific region of the film.

For example, a method for making a nanoparticle film comprising fused nanoparticles in film comprises: a) providing a film (e.g. a film having thickness of 5 to 500 nm) comprising a plurality of nanoparticles (e.g., quantum dots) disposed on a surface of a substrate (e.g., the substrate can be silicon, an inorganic material, a metal, or an organic polymer; and b) contacting a selected portion of the film with coherent radiation (e.g., have in wavelength of 400 to 20000 nm that can be provided by a laser such as, for example a continuous wave laser or a pulsed laser) such that 2 to 100 nanoparticles in the selected portion of the film are fused together and one or more size-dependent properties of the at least two nanoparticles in the selected portion of the film are altered.

The nanoparticles can be nanocrystals and/or quantum dots. For example, the quantum dots are selected from the group consisting of CdSe quantum dots, CdS quantum dots, CdTe quantum dots, PbSe quantum dots, PbS quantum dots, PbTe quantum dots, silicon quantum dots, germanium quantum dots, and combinations thereof. For example, the nanoparticles are selected from the group consisting of Au nanoparticles, Ag nanoparticles, FePt nanoparticles, Fe₂O₃ nanoparticles, and combinations thereof. Mixtures of nanoparticles (e.g., mixtures of one or more types of nanoparticle and/or one or more types of quantum dots) can be used. The nanoparticles can be disposed in a matrix material.

For example, a plurality of the selected portions of the film are be sequentially and/or simultaneously contacted with coherent radiation. For example, a plurality of exposed selected portions of the film are randomly or non-randomly distributed with respect to a plane parallel to the surface of the substrate on which the film is disposed. The selected portions of the film or exposed selected portions of the film can have a pre-defined shape in a plane parallel to the surface of the substrate on which the film is disposed and the individual selected portions have the same or different polygonal shape.

In an aspect, the present disclosure provides annealed (e.g., laser-annealed) nanoparticle films. The films may be disposed on a surface of a substrate. The films comprises one or more regions having one or more fused nanoparticles. For example, the fused nanoparticles comprise two or three independent nanoparticles fused together to form a fused nanoparticle.

For example, a laser-annealed nanoparticle film disposed on a surface of a substrate comprises one or more regions having one or more fused nanoparticles (e.g., the fused nanoparticles comprise two or three or more independent nanoparticles fused together to form a fused nanoparticle). A plurality of regions having one or more fused nanoparticles can be randomly or non-randomly distributed with respect to a plane parallel to the surface of the substrate on which the film is disposed. The regions having one or more fused nanoparticles can have a pre-defined shape in a plane parallel to the surface of the substrate on which the film is disposed and the individual selected portions have the same or different polygonal shape.

In an aspect, the present disclosure provides uses for the spatially-annealed films of the present disclosure. In an embodiment, a device comprises a spatially-annealed film. The spatially-annealed films can be used for light-emitting applications (e.g., nanoparticle LED displays such as quantum dot LED displays) and solid-state lighting applications (i.e., broad bandwidth nanoparticle light emitting diodes such as quantum dot light emitting diodes).

### BRIEF DESCRIPTION OF THE FIGURES

For a fuller understanding of the nature and objects of the disclosure, reference should be made to the following detailed description taken in conjunction with the accompanying figures.

FIG. 1. Schematic illustration of an example of the instant methods that create nanoparticle films with spatially patterned, controlled fusion to yield films with laterally patterned and graded optical and electronic properties.

FIG. 2. Schematic illustration of energy transport during laser spike annealing a). Laser radiation is converted to thermal energy by the Si substrate, and subsequently heat is transferred into and out of the NC film via conduction. Spatial and temporal profile of the laser anneal b). The red bar indicates the time spent above Tmax/2. Optical absorption and PL emission of as synthesized NCs c). Inset: TEM image of CdSe NC thin film; the scale bar is 20 nm.

FIG. 3. Detailed spatial profile of the annealing temperature across a 890° C. peak stripe a). Corresponding PL spectra acquired by scanning across a laser-annealed stripe b). Color correlates with the wavelength while saturation indicates PL intensity relative to the maximum intensity of a spectrum. Comparison of NC size obtained from PL measurements and SEM for a stripe with 2 ms dwell time c). Red whiskers and blue boxes represent the 5th, 25th, 75th and 95th percentile of the measured particles with the median value marked by large black dots. SEM images of the particle film showing increasing particle size with increased annealing temperature d). The scale bars indicate 20 nm.

FIG. 4. PL peak position can be controlled by both time and temperature a). The dashed box indicates the region studied in c. An Arrhenius plot of NC growth rate indicating a constant activation energy over two orders of magnitude of NC growth rate b). The black line indicates a linear fit to the data. Color indicates the peak PL wavelength of a data point. PL spectra showing a quantized transition during the first NC fusion event. PL spectra are normalized by the total emission c). The inset shows the change in particle diameter during the monomer to dimer fusion event. Illustration of the three steps involved in NC fusion, ligand degradation, neck formation, and surface diffusion to form a fully fused dimer d).

FIG. 5. PL spectra across a 3 mm region of periodic laser annealed stripes a). Spectra are normalized to the peak intensity. Color corresponds to wavelength and saturation to intensity as with FIG. 2. PL spectra of unannealed particles (U), a single laser annealed stripe (S), and the total emission from 5a (T) b). Emission spectra are normalized such that the total emission is constant. Location of the three emission spectra in b) on the CIE 1931 chromaticity diagram c). By changing the pitch of laser annealed stripes, any location on the dotted line is accessible.

FIG. 6. Peak PL wavelength across a laser stripe a). Black error bars indicate one standard deviation. Peak PL intensity across a laser stripe b). Green error bars indicate one standard deviation.

FIG. 7. Peak PL wavelength across a laser annealed stripe a). Peak PL wavelength as a function of annealing temperature b). Full PL spectra show a quantized transition between two NC populations c).

FIG. 8. Emission from a ‘cross-annealed’ nanoparticle film in which the first annealing was done as a vertical stripe followed by a second annealing in the horizontal direction. The figure demonstrates the ability to pattern the size-dependent properties in two dimensions in the film.

FIG. 9. PL data for core@shell CdSe@CdS quantum dots.

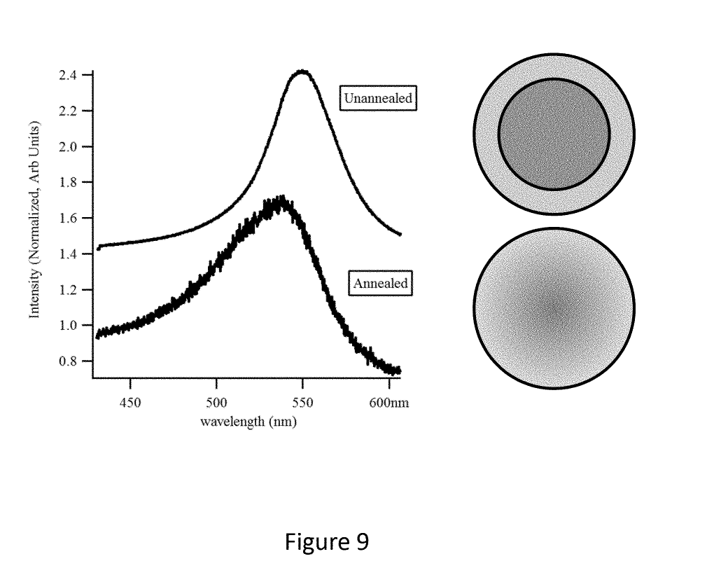

### DETAILED DESCRIPTION OF THE DISCLOSURE

Although claimed subject matter will be described in terms of certain embodiments and examples, other embodiments and examples, including embodiments and examples that do not provide all of the benefits and features set forth herein, are also within the scope of this disclosure. Various structural, logical, process step, and electronic changes may be made without departing from the scope of the disclosure.

Ranges of values are disclosed herein. All ranges provided herein include all values that fall within the ranges to the tenth decimal place, unless indicated otherwise, and ranges between the values of the stated range.

The present disclosure provides spatially-annealed nanoparticle films. Also provided are methods of making and using such films.

Much of the promise of nanomaterials derives from their size-dependent, and hence tunable, properties. Advances have been made in the synthesis of nanoscale building with precisely tailored size, shape and composition. Attention is now turning towards creating thin film structures in which size-dependent properties can be spatially programmed with high fidelity. Non-equilibrium processing techniques present exciting opportunities to nanostructured thin films with unprecedented spatial control over their optical and electronic properties. The present disclosure describes how laser spike annealing (LSA) on nanoparticle films, e.g., CdSe nanocrystal (NC) thin films, yields thin films with in which size dependent PL emission can be tuned, e.g., throughout the visible range and in spatially defined profiles, in a single annealing step. Through control over the annealing temperature and time it was established that NC fusion is a kinetically limited process with a constant activation energy over two orders of magnitude of NC growth rate. Lastly, the scalability of LSA to process large area NC films with periodically modulated PL emission, resulting in tunable emission properties of a large area film, was demonstrated. New insights into the processing-structure-property relationships described herein offer significant advances in our fundamental understanding of kinetic of nanomaterial fusion as well as technological implications for the production of nanomaterial films with periodically modulated optical properties.

In an aspect, the present disclosure provides methods of spatially annealing nanoparticle films. The methods are based on exposing/contacting specific regions of the film with focused light such that two or more of the nanoparticles in the specific region of the film are fused, which results in changes in the optical, electronic, and/or magnetic properties of the specific region of the film. Different regions of the films may be annealed differently resulting in different regions of the film having different optical, electronic, and/or magnetic properties. In an embodiment, an annealed (e.g., laser-annealed) nanoparticle (NC) film disposed on a surface of a substrate comprising one or more regions having one or more fused nanoparticles (fused NCs) is made using a method of the present disclosure.

An important result of the instant annealing process is that a gradient (e.g., a lateral gradient and/or vertical gradient with respect to the substrate surface on which the film is disposed) in the film properties may be formed, in contrast to discrete changes in the properties. The gradient may result at least in part from the fact that, in the case of laser-annealed films, the temperature profile of the substrate illuminated by the laser is not uniform, but generally has some Gaussian shape. As a result, regions of the film at the center, exposed to a higher power density, fuse more and regions at the edge fuse less.

In an embodiment, a method for making a nanoparticle (e.g., quantum dot or crystalline nanoparticle films) film comprising fused nanoparticles comprises: a) providing a film comprising a plurality of nanoparticles disposed on a surface of a substrate; and b) contacting (i.e., exposing) a selected portion of the film with focused radiation (e.g., coherent radiation) such that at least two nanoparticles in the selected portion of the film are fused together and one or more size-dependent properties of the at least two nanoparticles in the selected portion of the film are altered (e.g., the optical properties, electronic properties, and/or magnetic properties).

Various nanoparticle films can be used. It is desirable that the nanoparticles exhibit size-dependent properties. Examples of suitable nanoparticles include nanocrystals and quantum dots. These are referred to herein interchangeably. The nanoparticles can be metal nanoparticles, metal oxide nanoparticles, or semiconductor nanoparticles. The nanoparticles can have various surface chemistries, including, for example, oleic acid ligands (e.g., from the synthesis of the nanoparticles), or post-synthesis surface chemistry modifications including, for example, polymer-grafted ligands, short chain alkanes with carboxylate, thiol, amine binding groups or a combination thereof, and/or ionic ligands including, for example, halides or alkyl amines (e.g., methyl amine). Mixtures of two or more different nanoparticles can be used. The nanoparticles Examples of quantum dots include CdSe, CdS, CdTe, PbSe, PbS, PbTe, Si, and Ge quantum dots. Examples of suitable nanoparticles include Au, Ag, FePt, and Fe₂O₃. Nanoparticles can be obtained commercially or produced using methods known in the art. Nanoparticle films can by produced using methods known in the art.

For example, the nanoparticles are core-shell nanoparticles (core@shell) or core-shell-shell nanoparticles (core@shell1@shell2). The core and shell can be different materials. For example, the core and shell(s) are each selected from CdSe, CdS, CdTe, Pb Se, PbS, PbTe, Si, Au, Ag, FePt, or Fe₂O₃.

The nanoparticles can have various morphologies. The nanoparticles can be symmetric or asymmetric. For example, the nanoparticles are spherical, elongated rods, or platelets.

The nanoparticles can be heterostructures. For example, the nanoparticles are dot rods. The dot and rod can be different materials. For example, the dot and rod are each selected from CdSe, CdS, CdTe, Pb Se, PbS, PbTe, and Si quantum dots or Au, Ag, FePt, or Fe₂O₃ nanoparticles.

The nanoparticle film can be disposed on a variety of substrates. Without intending to be bound by any particular theory, it is considered that in certain cases the substrate is heated by the incident radiation and transfers heat to the nanoparticles. Examples of suitable substrates include silicon, metal oxides (e.g., transparent conductive oxides such as ITO or FTO, metals, and organic polymers. The substrate can be planar or non-planar.

The nanoparticles may be disposed in a matrix material. The matrix material can be an organic polymer. Examples of suitable matrix materials include organic polymers such as poly(methylmethacrylate) PMMA, polyvinylacetate (PVA), polystyrene, etc. The nanoparticles may engineered (e.g., surface modified) to work with other polymers with which they are not initially compatible. Dispersion in a flexible polymeric matrix provides the opportunity to peel the NP film off of the substrate after heating resulting in a flexible film.

A variety of sources of incident radiation can be used. The incident radiation may be coherent radiation, such as radiation from a laser. For example, incident radiation having a wavelength or wavelengths of 400 nm to 20000 nm can be used. Examples of suitable lasers includes continuous wave lasers (e.g., CO₂ (wavelength 10.6 um) and diode (0.4 to 20 um depending on the specific laser). Additional examples of suitable lasers include pulsed lasers (e.g., excimer lasers having a wavelength 380 nm).

The amount of focused radiation used for a specific area of the film is selected such that at least two or more nanoparticles in the region of the film over which the incident radiation contacts are fused. This can be referred to as controlled fusion—providing control (e.g., lateral control and/or through thickness control) over size-dependent properties. The amount of focused radiation is a function of the power per unit area of the incident radiation and the amount of time the region is exposed to the radiation. For example, an exposure time of 2 ms may require a power density of 10̂7 or 10̂8 W/m̂2, but for 20 ns exposure time significantly more power would be required and for 2s annealing less power would be required. The amount of focused radiation required is dependent on a variety of factors such as the substrate, contact time, nanoparticle materials, etc.

The amount of focused radiation used for a specific area of the film can be altered by using different ligands to surface passivate the nanoparticles which provides different nanoparticle surface energies. Examples of surface passivating ligands include, but are not limited to, carboxylic acids (e.g., oleic acid and acetic acid), amines (e.g., oleyl amine and methylamine), thiols, (e.g., dodecyl thiol and ethanethiol) and bifunctional ligands (e.g., ethane dithiol, oxalic acid, and mecaptoacetic acid). Without intending to be bound by any particular theory, it is considered that increasing the surface energy of the nanoparticles increases the nanoparticle fusion for a given dose of focused radiation. The amount of amount radiation used for a specific area of the film can also be altered modifying the surface chemistry of a portion or all of the nanoparticles used in the film. For example, a portion of the ligand shell (e.g., carboxylic acids (e.g., oleic acid and acetic acid), amines (e.g., oleyl amine and methylamine), thiols, (e.g., dodecyl thiol and ethanethiol) and bifunctional ligands (e.g., ethane dithiol, oxalic acid, and mecaptoacetic acid)) used to surface passivate nanoparticles) can be removed. Examples of methods of removing ligands from a nanoparticle surface are known in the art. For example, treatment of the nanoparticles with water or alcohol can remove up to and including 60% of the ligands while maintaining the ability of the nanoparticles to be in a colloidal suspension). In another example, halide treatment or oxide treatment are used to remove a part of the ligand shell of a part of or all of the nanoparticles. Without intending to be bound by any particular theory, it is considered that increasing the surface energy of the nanoparticles (e.g., using ligands with lower binding strength and/or removal of a portion of the surface passivating ligands) can increase nanoparticle fusion for a given dose of focused radiation.

The specific area(s) of the film contacted with (exposed to) focused radiation (e.g., coherent radiation) exhibit quantum-confined, size-dependent properties. In an example, the annealed film does not exhibit bulk properties across all of or at least a portion of the specific area(s) of the film contacted with (exposed to) the focused radiation (e.g., coherent radiation). As used herein, “bulk properties” are considered to be inherent properties of the material not influenced by the size of particles (if present) the system. This contrasts size-dependent properties that are generally defined by systems in which at least one-dimension is smaller than the Bohr exciton radius.

A variety of film thicknesses can be used. For example, the thickness of the film is of 5 nm to 500 nm, including all integer nm values and ranges therebetween.

Selected portions/regions of the film can be contacted with (i.e., exposed to) focused radiation in a variety of ways. For example, a plurality of selected portions of the film are sequentially and/or simultaneously contacted with coherent radiation. For example, a plurality of exposed selected portions of the film are randomly or non-randomly distributed with respect to a plane parallel to the surface of the substrate on which the film is disposed.

The selected portions of the film have a pre-defined shape (e.g., circular or polygonal shape) in a plane parallel to the surface of the substrate on which the film is disposed and the individual selected portions have the same or different polygonal shape. For example, the selected portions of the film are exposed to the focused radiation by rastering a laser in a pattern that forms a pre-defined shape. In an embodiment, the selected portion of the film is a line that may be discontinuous (i.e., discrete) or continuous (e.g., in a roll-to-roll manufacturing process).

The selected portion of the film can have a variety of sizes. For example, the selected portion of the film is 50 to 100 um in the direction perpendicular to the scan direction where the particles go from unfused to fused and back, producing the spatially modulated properties. The selected portion(s) of the film can be 1 to 100% of the film area, including all integer % values and ranges therebetween. The selected portions of the film may at least partially overlap. This results in a portion (the overlapping selected portion(s)) of the film being contacted with incident radiation two or more times.

Nanoparticles in the selected area of the film are fused. For example, depending on the amount of focused radiation used and the size of the specific area, 2 to 100 nanoparticles in the individual selected areas of the film are fused. In various examples, 2 to 10, 2 to 25, or 2 to 50 nanoparticles in the individual selected areas of the film are fused.

One or more size-dependent property (e.g., optical properties, electronic properties, and/or magnetic properties) in one or more selected portion of the film are altered. For example, in the case of size-dependent optical properties, the energy gap (characteristic for size-dependent light absorption and emission relevant to optoelectronic device) can be altered (e.g., tuned) such that it has a value from the infrared through the visible into the ultraviolet) In the case where the film comprises two or more different nanoparticles, two nanoparticles of different compositions can be fused resulting in formation of a fused nanoparticle of a new material having different composition and properties than the individual nanoparticles. The formation of the fused nanoparticles of a new material can be carried out in a spatially-defined manner.

The steps of the method described in the various embodiments and examples disclosed herein are sufficient to carry out the methods of the present invention. Thus, in an embodiment, the method consists essentially of a combination of the steps of the methods disclosed herein. In another embodiment, the method consists of such steps.

In an aspect, the present disclosure provides annealed (e.g., laser-annealed) nanoparticle films. The films may be disposed on a surface of a substrate. The films comprises one or more regions having one or more fused nanoparticles. For example, the fused nanoparticles comprise two or three independent nanoparticles fused together to form a fused nanoparticle.

The annealed film comprises a plurality of regions having one or more fused nanoparticles are randomly or non-randomly distributed with respect to a plane parallel to the surface of the substrate on which the film is disposed. The regions having one or more fused nanoparticles have a pre-defined shape (e.g., circular or polygonal shape) in a plane parallel to the surface of the substrate on which the film is disposed and the individual selected portions have the same or different polygonal shape.

The annealed film can have one or more fused nanoparticles of a new material having different composition and properties than the individual nanoparticles. The film may comprise one or more regions having fused nanoparticles of a new material having different composition and properties than the individual nanoparticles used to form the film.

In an aspect, the present disclosure provides uses for the spatially-annealed films of the present disclosure. In an embodiment, a device comprises a spatially-annealed film. Examples of suitable devices are known in the art.

The spatially-annealed films can be used for light-emitting applications (e.g., nanoparticle LED displays such as quantum dot LED displays) and solid-state lighting applications (i.e., broad bandwidth nanoparticle light emitting diodes such as quantum dot light emitting diodes). Accordingly, in various embodiments, a light-emitting device or solid-state lighting device comprises a spatially-annealed nanoparticle film.

The ability to create nanoparticle-thin films with lateral gradients in size-dependent properties can also be attractive for photodetector applications. Accordingly, in an embodiment, a photodetector comprises a spatially-annealed nanoparticle film.

Lateral gradients of nanoparticles with magnetic properties can be interesting for data storage applications. Lateral gradients of nanoparticle thin films with lateral gradients in size-dependent emission can also be interesting for applications in bio-sensing (e.g., multiplexed analyte detection). Accordingly, in various embodiments, a data storage device or bio-sensing

The following examples are presented to illustrate the present disclosure. They are not intended to limiting in any matter.

### Example 1

The following describes an example of the annealing method of the present disclosure and characterization of a product thereof.

Described is a complementary top-down processing technique, laser spike annealing, that can be applied to create spatially modulated properties of a nanomaterial at the μm to mm length scale. CdSe NCs was used as a model system and it was shown that laser annealing of nanoparticle thin films can be optimized to rigorously control the fusion of proximate dots in the film to provide unprecedented control over the spatially patterned photoluminescene (PL) emission profile. This innovation also enabled scientific advances in the form of fundamental insights into the activation energy and mechanism underlying the controlled nanoparticle (e.g., QD) fusion process. Combined control over dwell time and annealing temperature enabled a showing that sintering of nanoparticles (e.g., CdSe) is a kinetically activated process with, for example, a constant activation energy over two orders of magnitude of nanoparticle growth rate. By reducing the annealing time to submillisecond time scales, the initial stages of NC fusion were kinetically trapped and determine that the NCs undergo quantized transitions similar to magic sized clusters observed in NC synthesis. Moreover, the ability to precisely control the size of NC and the spatial position within the film opens exciting opportunities to create thin films with rigorously programmable photoluminescence emission profiles. By taking advantage of the tunable emission, production of large area films that emit light across the visible spectra with tunable CIE values was demonstrated. In light of the prominent and growing role of size tunable properties of functional nanomaterials, the ability to produce tunable gradients in nanomaterial (e.g., nanoparticle) properties is a promising laser annealing processing tool with applications beyond the model system described in this example.

Laser annealing provides a powerful and versatile processing technique to treat nanostructured materials under conditions that would, under conventional, equilibrium, processing conditions lead to sintering and loss of nanostructure. Specifically, laser spike annealing (LSA) is a top down processing method developed by the integrated circuit industry to control dopant diffusion. LSA is an inherently non-equilibrium processing method that can provide kinetic insight at time scales that are difficult to achieve with conventional processing techniques. LSA experiments described in this paper employed a CO2 laser (λ=10.6 μm) that is focused into a 2D Gaussian profile and is scanned across a sample.

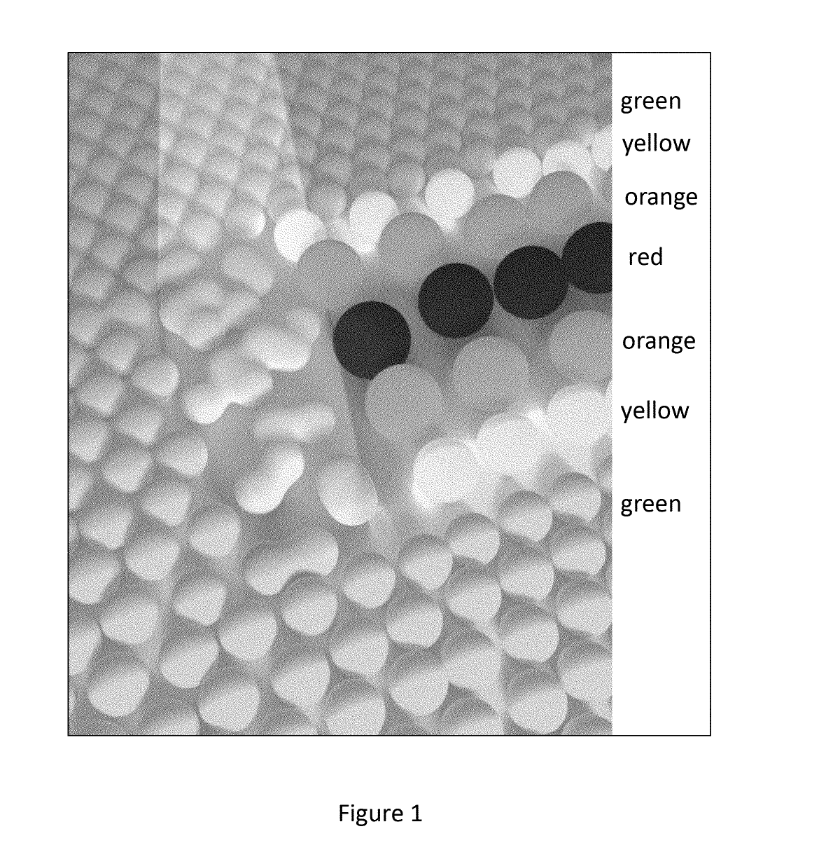

FIG. 1 provides a schematic illustration of the laser-induced controlled fusion of nanoparticles in the thin film. Nanoparticles fuse from ‘monomer’ building blocks to yield dimers, and oligomers. Importantly, the controlled fusion occurs over a spatial region defined by the lateral temperature gradient created in the laser annealing (i.e., micrometers).

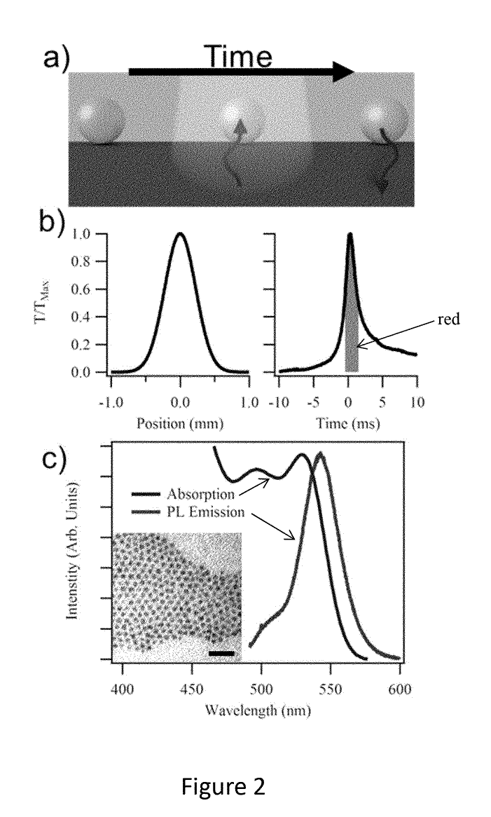

Detailed aspects of the controlled nanoparticle fusion are illustrated in in FIG. 2a; NCs in the thin film are transparent to the incident laser beam and are instead heated by conductive heat transfer from the underlying highly doped Si substrate which absorbs the energy from the laser. This substrate therefore acts as both a heat source during heating and a heat sink after the laser has passed, resulting in a rapid quench from high temperatures. For NC films, the thermal diffusion length (˜500 nm in 1 us) is significantly larger than the average film thickness (typically ˜50 nm), ensuring that the film is processed uniformly.

The spatial and temporal temperature profile encountered during single stripe LSA are summarized in FIG. 2b. The Gaussian profile perpendicular to the scan direction leads to a spatial variation in the peak annealing temperature with a typical temperature gradient of 1-2° C./μm. The ratio of the FWHM of the laser beam parallel the scan direction (80 μm) to the scan rate as the laser dwell time was defined. It was determined that the optimum dwell time for processing of colloidal NCs to be 250 μs to 2 ms and focus on that range in the discussion below.

The choice of CdSe NCs as a model system for the laser annealing of nanoparticle thin films leveraged the extensive knowledge base of size-dependent optical properties and rigorous synthetic control over CdSe NC size and shape. Briefly, in NCs with a radius smaller than the Bohr exciton radius (˜6 nm for CdSe) quantum confinement effects lead to an increase in the NC energy gap roughly proportional to r-n (n˜1.5). In the specific case of CdSe NCs, the energy gap can be conveniently tuned across the visible spectrum.

FIG. 2c summarizes the optical properties of the CdSe NCs starting materials; the spectra show the excitonic absorption peak centered at 530 nm and the emission peak at 545 nm (FWHM=30 nm). By combining the size-dependent optical properties and statistical analysis of TEM images (inset FIG. 2b) the average NC diameter was determined to be 2.8 nm+/−8%. The well-established size-dependent optical properties provide a convenient metric to monitor changes in the NC size; this effect has previously been exploited to monitor the evolution of NC size during synthesis as well as changes in particle size after steady state thermal annealing of NC thin films.

It was hypothesized that the ability to create temperature gradients with steep spatial profiles will enable the fabrication of structures in which the fusion of proximate NCs in a thin film can be carefully controlled and even spatially patterned. To test this hypothesis, single laser stripes across the CdSe NCs thin film were scanned and the evolution of the NC structure using a combination of optical spectroscopy and electron microscopy probed.

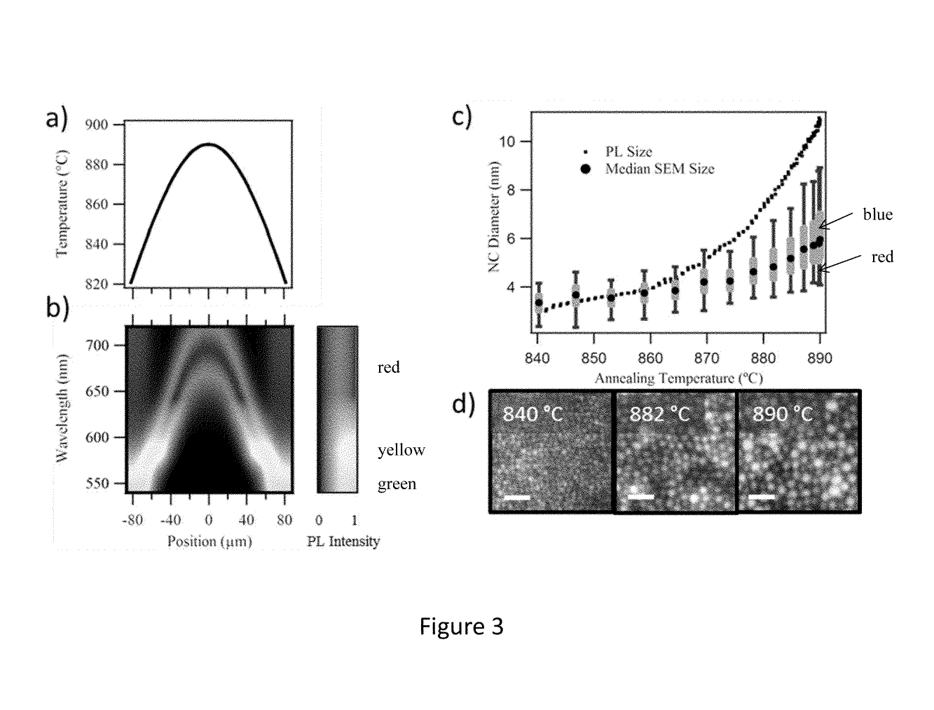

Spatial maps of the NC PL emission spectrum provide important insight into the local variation of NC size. Based on the well-known size-dependent optical properties, a change in NC size can be inferred from a shift in the emission spectrum. In FIG. 3 the spatial temperature profile near the center of a laser annealed stripe is compared with a peak temperature of 890° C. and a dwell time of 2 ms with the resulting PL emission spectra collected from a series of scans across the stripe. The PL map (FIG. 3b), clearly shows a systematic red shift of the NC emission towards the center of the laser-annealed strip.

The observed spatial gradient in the PL emission stands in excellent agreement with the temperature gradients produced by laser annealing. The largest redshift in the emission spectra, implying the largest amount of NC fusion, occurs at the peak annealing temperature, whereas adjacent regions of the film annealed at lower temperatures show a reduced redshift compared to the initial particles. The emission spectra of initial NCs can be seen at the edges of the scans in areas annealed below 840° C. Importantly, these results show that the PL emission from CdSe NCs can be tuned across the visible spectrum by laser annealing, limited only by the size of the initial NCs.

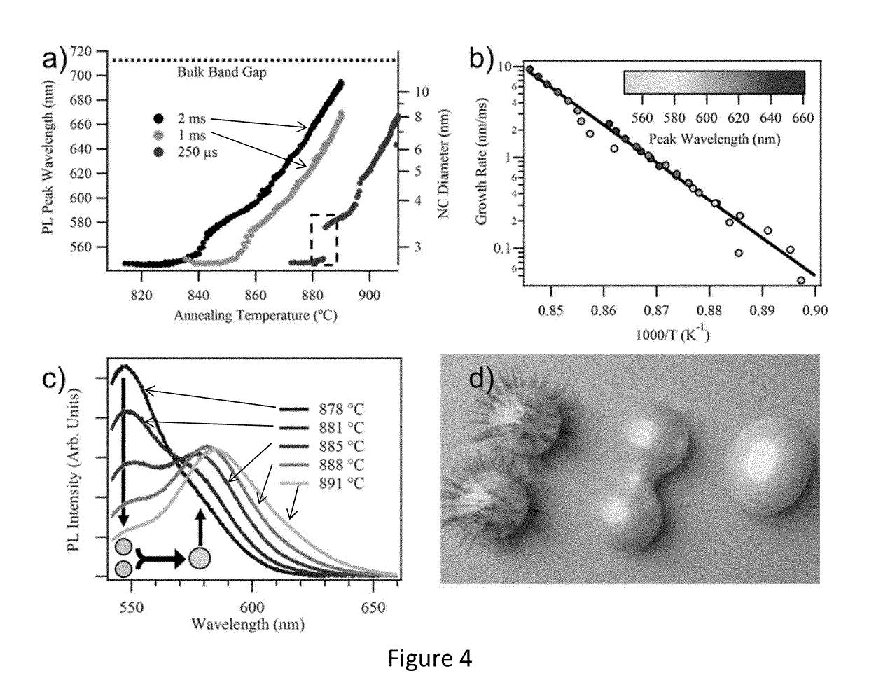

To confirm that the observed shift in PL emission is due to spatial variation in NC size, the structure of annealed stripes using scanning electron microscopy (SEM) was examined. FIG. 4 compares the NC diameter distribution determined from statistical analysis of SEM images to the NC size inferred from size-dependent PL emission spectra. The size of NC from the PL emission peak was estimated (as described in this example) based on a polynomial fit to a set of CdSe NCs reported in previous studies. The side-by-side comparison of SEM and PL results reveals an interesting systematic deviation; at high temperatures, the NC diameter inferred from the PL emission is significantly larger than the particle size distribution observed by SEM. The deviation between SEM and PL results can be attributed to two factors: first, SEM only probes the top layer of the film. While it was expected that the entire film would experience the same time-temperature profile, the NCs at the top of the assembly are less coordinated with neighboring dots compared to NCs in the middle of the film. With fewer neighbors, NCs in the top layer are unable to sinter during thermal annealing. The second factor contributing to the trends evident in FIG. 3 is that the measured PL emission do not reflect the average NC size, but instead must be understood in context of the polydisperse nature of annealed films. In NC films, Förster resonant energy transfer (FRET) from small NCs (large energy gap) to large NCs (small energy gap) is well established. Consequently, PL measurements provide a measure of the largest NCs in a film rather than a measure of the average particle size.

To better understand how basic thermodynamic and kinetic factors impact the non-equilibrium NC fusion, the combined time and temperature dependence of NC fusion was studied. In a previous study, a qualitative kinetic model was developed to explain the change in film morphology under different laser annealing conditions using a NC diffusion length ld=\sqrt{4Dτ} where D is the temperature dependent diffusion coefficient of NCs in a film and τ is the dwell time. It was concluded that processing NC films under conditions such that ld exceeds the inter-NC spacing lead to particle sintering. In agreement with this qualitative kinetic model, our current work shows that both higher annealing temperatures and longer annealing times lead to increased redshift in the emission spectra, and hence increased fusion in the NC film (see FIG. 4a).

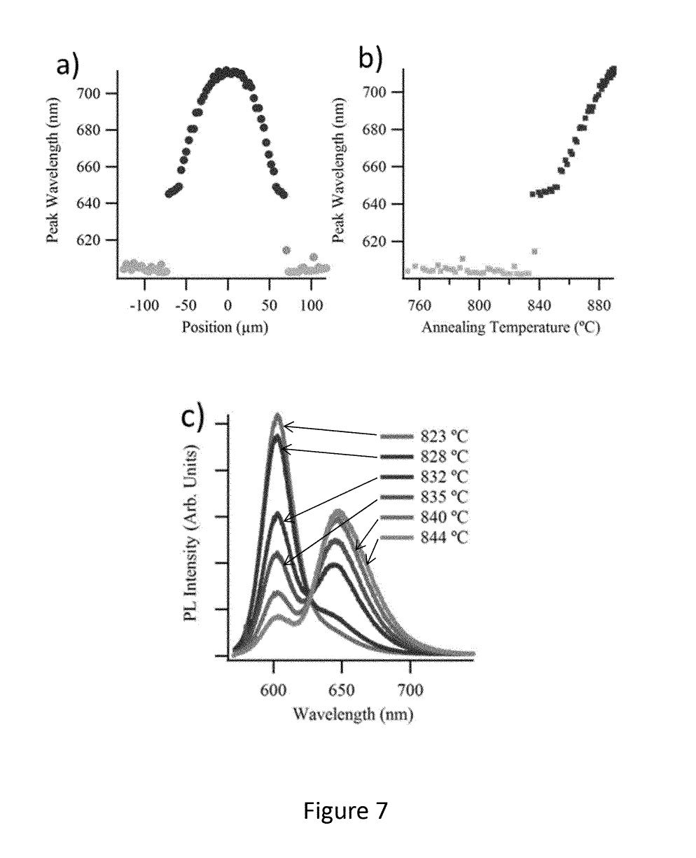

The combination of well-defined spatial temperature gradients and high spatial resolution probe of the PL emission present opportunities to improve upon our earlier model and gain more detailed insights into the energetics of NC fusion. To provide a quantitative analysis, the NC growth rate was defined as the change in NC radius, determined by our PL fitting curve, divided by the dwell time. For kinetically controlled, i.e., thermally activated, NC fusion the growth rate should follow an Arrhenius relationship. FIG. 4b shows the NC growth rate on a logarithmic scale against the inverse annealing temperature. For clarity, data from 560 to 660 nm is shown only in 10 nm increments, the full data set is shown in FIG. 7. The black line in FIG. 4b represents a fit to the Arrhenius relationship corresponding to an activation energy of 8.4 eV. Although the Arrhenius model provides a good description of the overall experimental trends, a systematic deviation from the trend line for small NCs with peak emission below 610 nm was noted.

To understand the deviation of small NCs from the Arrhenius relationship in FIG. 4b the full PL spectra was examined rather than just the PL peak position and consider the nature of the initial fusion events in a NC film. The evolution of PL spectra during NC fusion is most clearly revealed in a NC film annealed at 250 μs with a peak temperature of 910° C.; this annealing time enables kinetic trapping of NC populations that are less distinct at longer annealing times. For the initial stages of NC fusion displayed in FIG. 4c, the PL spectra show a discrete transition between two peaks at 550 nm and 580 nm. The location of these peaks correlate with CdSe NCs with a diameter of 2.8 nm (the initial NC monomer) and 3.5 nm (a NC dimer)(see FIG. 4d). The above Arrhenius analysis is based on the assumption that PL comes from a monomodal distribution of emitters with the PL peak position as a good measure of the size of the emitters. For the multimodal emission spectra presented at short time scales and/or lower temperatures, this assumption does not hold, leading to the observed systematic deviation from the Arrhenius trend. The initial NC fusion results in a change in PL peak intensity between two distinct populations rather than a continuous shift in PL peak position, resulting in erroneous NC growth rates.

The results of both our kinetic analysis of NC growth and the observed discrete fusion events among monomer and dimer particles can be understood in context of a three-step particle fusion process suggested by previous in situ TEM and small angle X-ray scattering studies of NC sintering and illustrated in FIG. 4d. The NC fusion process involves: first, removal of the ligands that provide steric repulsion, second, the formation of bridges between NCs, which requires NC to move into contact and sometimes rotate to orient their crystallographic axis, and finally rapid fusion into a single particle via surface diffusion.

The observation of a constant activation energy over a range of NC sizes and growth rates provides a strong inference for the presence of a single rate-limiting process. As ligand removal is a prerequisite to NC fusion, it cannot be the rate limiting step for growth of NCs that have already undergone fusion. Likewise, diffusion of surface atoms was eliminated as the rate-limiting step based on the discrete shift in emission spectra for small particles. If surface diffusion were rate limiting, it would be expected to see emission from partially fused dimers, as observed in PbSe dimers formed in solution. The emission expected from a partially fused CdSe dimer would occur at 660 nm, which was not observed. Moreover, the activation energy for self-diffusion in the bulk for Cd or Se at the temperatures studied is 1.5 eV, significantly below the measured activation energy, even without accounting for the fact that surface diffusion faces a lower activation energy compared to bulk diffusion. It was therefore concluded that the formation of a neck between NCs defines the rate-limiting step for NC fusion.

Building on the understanding of and control over spatial gradients in NC fusion established above, a proof-of-principle demonstration of how spatial control of the NC fusion process can be applied to NC light emitting applications was carried out. CdSe NCs have attracted significant interest in solid state lighting and display applications by virtue of their tunable and narrow emission spectrum. Conventional solid state lighting typically combine a blue LED with a yellow phosphor, generating white light with high efficiency but a poor color rendering index (CRI). The CRI can be improved by adding a red emitting phosphor, but at the cost of lower efficiency due to emission in the IR.

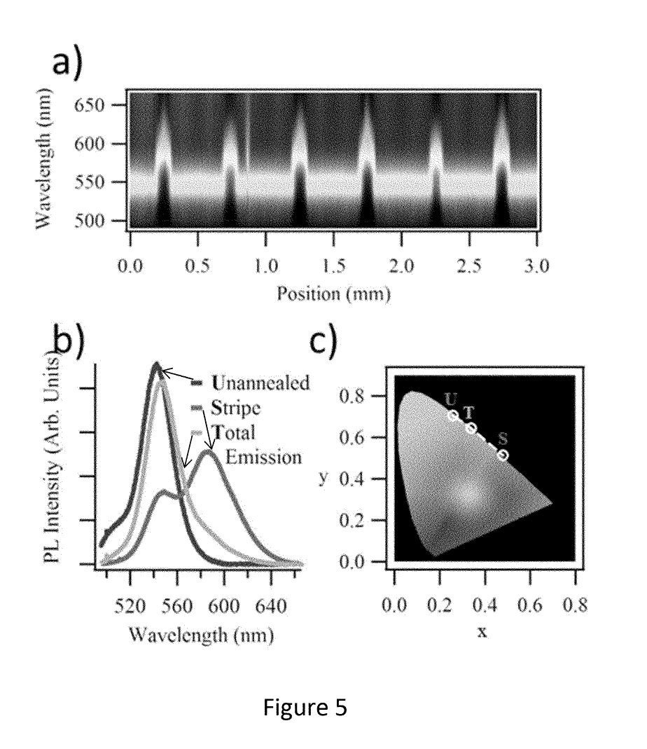

Building on the ability to spatially tune the emission properties of NC films via LSA, the fabrication of functional CdSe NC emitter films with tunable emission profiles defined by the peak annealing temperature and spacing between stripes was demonstrated. This is an important advance beyond previous studies, the emission spectrum of a NC film was tuned starting from the same NC monomers as building blocks and the film emission defined through processing rather than by mixing together NCs of different sizes. Moreover, this approach provides unprecedented opportunity to precisely program the spatial resolution of the NC emission. FIG. 5a shows the emission spectra across a 3 mm wide area where stripes have been laser annealed at a peak temperature of 860° C. with a dwell time of 2 ms and a pitch of 500 The peak annealing temperature stripes were deliberately limited to control the fusion of the monomer to form dimers. Annealing at the higher temperatures required to achieve additional NC fusion leads to a decrease in PL intensity, likely due to a combination of film ablation and decreased QY. The emission spectra of an unannealed film (U), the 120 μm wide stripe (S), and the total emission from FIG. 5a (T) are presented in FIG. 5b. Compared to the emission from the unannealed film, the total emission shows a slight redshift in the main emission peak as well as a tail of emission extending out to higher wavelengths. As a result of the change in the PL emission profile, the CIE coordinates of the NC film change, as shown in FIG. 5c. In principle, any emission wavelength on the dotted line connecting U and S can be accessed by simply changing the pitch of a laser annealed striped, while the coordinates of S can be changed by controlling the peak annealing temperature. Combined with a high efficiency blue LED, these LSA NC films therefore have the potential to produce white light with tunable CIE coordinates and high CRI.

The fusion of CdSe NC films was studied with an unprecedented level of detail. By combining a steep temperature gradient from single stripe laser annealing with high-resolution spectroscopic and microscopic characterization. It was shown that laser-annealed NCs sinter via a kinetically limited process with a constant activation energy over two orders of magnitude of NC growth rate and identify the rate limiting step as the formation of necks between pairs of NCs. To underscore the broader technological implications of this work, it was shown how periodic modulation of the NC PL properties via laser annealing can change the CIE coordinates of the NC film emission, to enable tunable film properties from a single NC feedstock.

Materials and Methods. Chemicals. NC synthesis and thin film preparation. CdSe NC synthesis followed a previously published procedure from Carbone et al. For the NC absorbing at 535 nm studied in the main text, 60 mg of CdO, 280 mg ODPA, and 3 grams of TOPO were added to a three neck flask. The solution was degassed under vacuum at 150° C. for an hour. The solution was heated above 300° C. under nitrogen and 1.5 grams of TOP was injected into the flask. Finally the solution was heated to the injection temperature of 380° C. and 450 ul of 1.7 M TOP:Se, from a stock solution made in a nitrogen glovebox, was injected. The reaction solution was immediately removed from heat. When the reaction cooled to 160° C., it was quenched by injecting 10 ml of toluene. The particles were washed 3 times using ethanol/hexane as the solvent/antisolvent pair and stored in a nitrogen glovebox until used.

NC films for laser annealing were produced by spincoating a 10 mg/ml solution of particles in hexane at 2000 rpm for 30 seconds. Substrates were cleaned via sonication in acetone and IPA for 5 min each followed by 10 min of UV ozone treatment.

Laser annealing. Characterization. Absorption measurements were performed using a Cary 5000 UV-vis spectrometer. PL mapping was performed using a Renishaw confocal Raman microscope. The NCs were excited by a 488 nm laser with a maximum power of 5 mW. Scanning electron microscopy was performed using a LEO 1550 FESEM with a working distance of 3 mm and an accelerating voltage of 5 kV.

Calculation of emission position for a partially fused dimer. The expected PL emission for a partially fused dimer particle was calculated using the framework developed by Huges et al.

Calculation of thermal diffusion length. Second Quantized Fusion Step. The second sharp jump in the PL emission-temperature trace for a dwell time of 250 μs suggests another quantized NC fusion event. Compared to the transition from monomer to dimer emission, the second quantized transition is less clear. The PL attributable to the dimer population decreases, and a peak appears corresponding to NCs with a total volume of 4 ‘monomer’ particles, i.e., ‘tetramers’. The 1-2-4 pattern of NC fusion has been observed previously for Au NCs during HRTEM studies. The PL signature for the dimer-tetramer transition is less clear for two reasons. First, as noted above, due to FRET in NC films PL is a measure of the largest NCs in the ensemble rather than an average. Fusion from monomers into dimers leads to a less uniform film where the precise local NC population will effect both the PL emission and subsequent fusion events. In addition, for larger CdSe NCs, the change in emission wavelength with increasing radius is smaller resulting in greater overlap between the emission between the discreet NC populations. Eventually, the change in PL emission wavelength after a NC fusion event becomes small enough that the PL emission becomes monomodal and red shifts continuously with increasing temperature. A video of the changing spectra across a NC stripe is included in the SI, and makes the transition between quantized and continuous PL shift clear.

Whereas PL spectra provide clear indication of the initial NC fusion from ‘monomers’ to ‘dimers’, the nature of the subsequent fusion events is less obvious. It was hypothesized that fusion into dimers occurs first between NCs that have lost their ligands most quickly. Subsequently, it is likely that fusion of a dimer with a monomer and fusion with a dimer are two competing processes. Because dimers have already lost enough ligands to become destabilized and fuse, dimer-dimer fusion will have one less barrier to fusion whereas dimer-monomer fusion will require destabilization of the monomer and be a relatively slower process. The interpretation of ‘activated’ particles involved in NC fusion events is further supported by recent in-situ study of heterogeneous NC fusion at elevated temperatures.

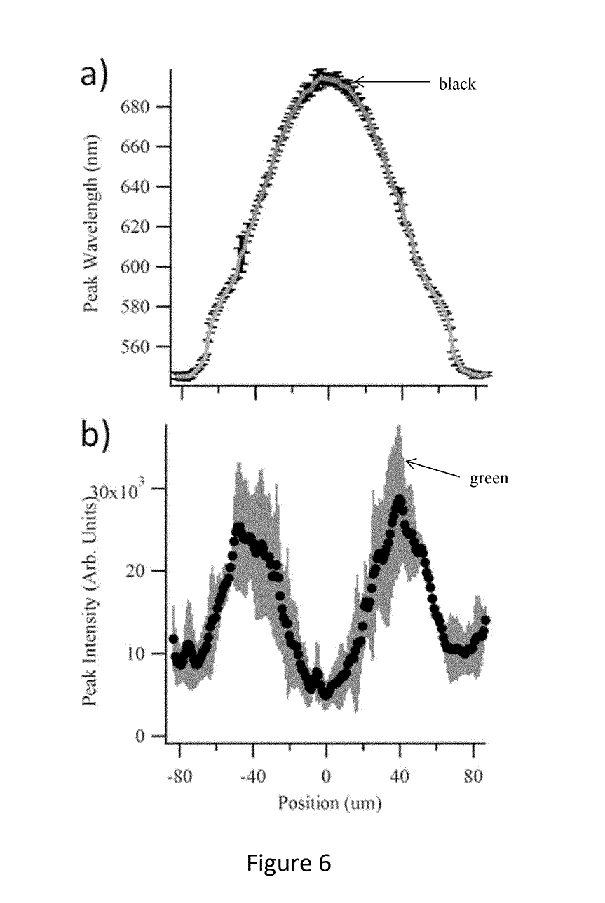

PL Intensity. Unlike the PL peak position, the PL intensity across the laser annealed stripes does not show a simple trend. FIG. 6b shows the total PL emission across a 2 ms dwell time, 890° C. peak temperature annealing stripe. The green bars indicate the standard deviation in intensity based on 6 separate measurements. For comparison, FIG. 6a shows the PL peak position similarly averaged across 6 measurements. There is significantly more deviation in the PL intensity, which was attributed to non-uniformity in the spincoated NC film.

The PL intensity detected by the Raman microscope can be described by equation 1:

PL Intensiy=η_{Detector}φₚₕₒₜₒₙ(1−exp(−αt))QY eq 1

Where η is the detector efficiency, φ is the photon flux, a is the absorption coefficient at 488 nm, t is the film thickness, and QY is the QY of the emitting NCs. The change in detector efficiency across the range of wavelengths could only account for up to a 30% relative increase in detected PL. The laser intensity, and hence photon flux is constant throughout the measurement. Given the sensitivity of NC to surface passivation, increased quantum yield after degradation of the ligand shell and fusion of NCs seems unlikely. The most likely reason for the initial increase in PL intensity is increased absorption of the laser resulting from a changing local dielectric constant and a change in the NC bandgap. The decrease in PL for the highest annealing temperatures (the center of the stripe) is likely due to ablation of NCs during laser annealing as a result of the decomposition of the organic ligands. Both the mechanism for increased PL emission, as well as film loss due to ablation during laser annealing will require further investigation to address more fully.

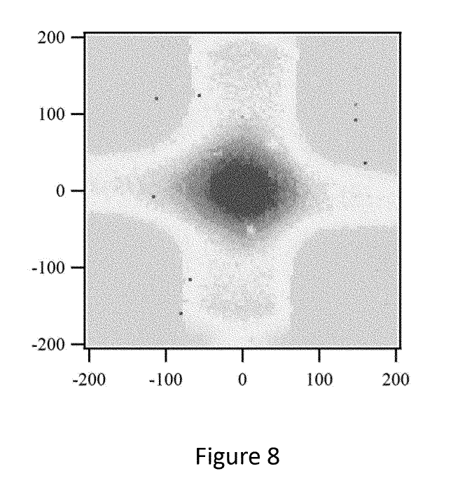

Cross Annealing. To move beyond the study of individual laser annealed stripes and to NC films with periodically modulated properties knowledge of the effects of multiple annealing steps on NCs is necessary. In order to study the effect of multiple annealing steps on NC films, two laser stripes perpendicular to each other were annealed. Due to the Gaussian nature of the thermal profile, one intersection provides information on a wide range of possible processing combinations. In FIG. 8, first a stripe was annealed vertically at 850° C., just above the transition to emission dominated by dimers. Then the sample was rotated 90 degrees and a stripe was annealed at 840° C., just below the transition to emission dominated by dimers. While the additional fusion at the intersection of the two annealing peaks is expected. It was seen in the laser cross annealing that annealing at a lower temperature can still lead to additional fusion in the films. No additional fusion is observed for secondary annealing temperatures below 800° C. (preliminary result, to be replaced with more accurate and thorough discussion later.)

PL sizing curve. In order to relate the PL emission wavelength to the diameter of laser annealed NCs, reports of PL emission from CdSe NCs synthesized under similar reaction conditions were aggregated. A third order polynomial fit to the data was used in order to generate an empirical PL sizing curve which was used in this example.

Laser Spike Annealing of larger CdSe NCs. Laser spike annealing on 4.1 nm CdSe particles was performed in order to confirm that the NC sintering behavior discussed in the main text is typical for CdSe NCs. Annealing of a film with a dwell time of 2 ms and a peak temperature of 890° C., matching the conditions of FIG. 3, results in gradients in PL emission that show the same features as the 2.7 nm particles.

What is claimed is:

1. A method for making a nanoparticle film comprising fused nanoparticles in film comprising:
a) providing a film comprising a plurality of nanoparticles disposed on a surface of a substrate; and
b) contacting a selected portion of the film with coherent radiation such that 2 to 100 nanoparticles in the selected portion of the film are fused together and one or more size-dependent properties of the at least two nanoparticles in the selected portion of the film are altered.

2. The method of claim 1, wherein the nanoparticles are quantum dots.

3. The method of claim 2, wherein the quantum dots are selected from the group consisting of CdSe quantum dots, CdS quantum dots, CdTe quantum dots, PbSe quantum dots, PbS quantum dots, PbTe quantum dots, silicon quantum dots, germanium quantum dots, and combinations thereof.

4. The method of claim 1, wherein the nanoparticles are selected from the group consisting of Au nanoparticles, Ag nanoparticles, FePt nanoparticles, Fe₂O₃ nanoparticles, and combinations thereof.

5. The method of claim 1, wherein the substrate is silicon, an inorganic material, a metal, or an organic polymer.

6. The method of claim 1, wherein the nanoparticles are disposed in a matrix material.

7. The method of claim 1, wherein the coherent radiation is provided by a continuous wave laser or pulsed laser.

8. The method of claim 1, wherein the coherent radiation has a wavelength of 400 to 20000 nm.

9. The method of claim 1, wherein the thickness of the film is of 5 to 500 nm.

10. The method of claim 1, wherein a plurality of the selected portions of the film are sequentially and/or simultaneously contacted with coherent radiation.

11. The method of claim 1, wherein a plurality of exposed selected portions of the film are randomly or non-randomly distributed with respect to a plane parallel to the surface of the substrate on which the film is disposed.

12. The method of claim 8, wherein the selected portions of the film or exposed selected portions of the film have a pre-defined shape in a plane parallel to the surface of the substrate on which the film is disposed and the individual selected portions have the same or different polygonal shape.

13. The method of claim 9, wherein the selected portions of the film or exposed selected portions of the film have a pre-defined shape in a plane parallel to the surface of the substrate on which the film is disposed and the individual selected portions have the same or different polygonal shape.

14. A laser-annealed nanoparticle film disposed on a surface of a substrate comprising one or more regions having one or more fused nanoparticles.

15. The laser-annealed nanoparticle film of claim 11, wherein the fused nanoparticles comprise two or three independent nanoparticles fused together to form a fused nanoparticle.

16. The laser-annealed nanoparticle film of claim 11, wherein a plurality of regions having one or more fused nanoparticles are randomly or non-randomly distributed with respect to a plane parallel to the surface of the substrate on which the film is disposed.

17. The laser-annealed nanoparticle film of claim 15, wherein the regions having one or more fused nanoparticles have a pre-defined shape in a plane parallel to the surface of the substrate on which the film is disposed and the individual selected portions have the same or different polygonal shape.
